(19) United States
(12) Patent Application Publication
(10) Pub. No.: US 2008/0258192 A1
(43) Pub. Date: Oct. 23, 2008

(54) SEMICONDUCTOR DEVICE AND MANUFACTURING METHOD THEREOF

(76) Inventors: Soichi YAMAZAKI, Yokohama-shi (JP); Koji Yamakawa, Tokyo (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/104,138

(22) Filed: Apr. 16, 2008

(30) Foreign Application Priority Data
Oct. 3, 2006 (JP) 2006-271900

(51) Int. Cl. H01L 29/92; H01L 21/02

(52) U.S. Cl. 257/295; 438/3; 257/E29.342; 257/E21.008

(57) ABSTRACT

This disclosure concerns a semiconductor device comprising an insulating film provided on a semiconductor substrate; a lower contact formed in the insulating film; a ferroelectric capacitor including a first lower electrode provided on the lower contact and connected to the lower contact, a second lower electrode provided on the first lower electrode and made of SRO (Strontium Ruthenium Oxide), a ferroelectric film including crystals, and an upper electrode provided on the ferroelectric film, grain diameters of the crystals being set to 30 nm to 150 nm by forming the ferroelectric film on the second lower electrode; and a wiring connected to the upper electrode.

### CROSS-REFERENCE TO RELATED APPLICATION

The disclosure of Japanese Patent Application No. 2006-271900, filed on Oct. 3, 2006, including the specification, drawings and abstract is incorporated herein by reference in its entirety.

### BACKGROUND OF THE INVENTION

1. Field of the Invention

The present invention relates to a semiconductor device and a semiconductor device manufacturing method. For example, the present invention relates to a semiconductor device including a ferroelectric film capacitor cell structure and a manufacturing method therefor.

2. Related Art

A ferroelectric memory device includes memory cells each constituted by a ferroelectric capacitor using a ferroelectric material. This ferroelectric capacitor is configured to include a lower electrode, a ferroelectric dielectric film provided on the lower electrode, and an upper electrode provided on the ferroelectric dielectric film. However, the conventional ferroelectric capacitor has a problem that a voltage at which polarization of the ferroelectric is inverted is high (a so-called inversion electric field is high). If the inversion electric field of the ferroelectric capacitor is high, the ferroelectric memory device may possibly malfunction to follow high integration of the ferroelectric memory device and reduction in driving voltage. This disadvantageously deteriorates reliability of the ferroelectric memory device.

### SUMMARY OF THE INVENTION

A semiconductor device according to an embodiment of the present invention comprises an insulating film provided on a semiconductor substrate; a lower contact formed in the insulating film; a ferroelectric capacitor including a first lower electrode provided on the lower contact and connected to the lower contact, a second lower electrode provided on the first lower electrode and made of SRO (Strontium Ruthenium Oxide), a ferroelectric film including crystals, and an upper electrode provided on the ferroelectric film, grain diameters of the crystals being set to 30 nm to 150 nm by forming the ferroelectric film on the second lower electrode; and a wiring connected to the upper electrode.

A semiconductor device according to an embodiment of the present invention comprises an insulating film provided on a semiconductor substrate; a lower contact formed in the insulating film; a ferroelectric capacitor including a first lower electrode provided on the lower contact and connected to the lower contact, a second lower electrode provided on the first lower electrode, a ferroelectric film formed on the second lower electrode, and an upper electrode provided on the ferroelectric film, the second lower electrode being made of SRO and having a thickness equal to or larger than 5 nm; and a wiring connected to the upper electrode.

A method of manufacturing a semiconductor device according to an embodiment of the present invention comprises, the method comprises forming an insulating film on a semiconductor substrate; forming a lower contact in the insulating film; forming a first lower electrode on the lower contact to be connected to the lower contact; forming a second lower electrode made of SRO on the first lower electrode; forming a ferroelectric film on the second lower electrode to set grain diameters of crystals of the ferroelectric film to 30 nm to 150; forming an upper electrode on the ferroelectric film; and forming a wiring to be connected to the upper electrode.

### BRIEF DESCRIPTION OF THE DRAWINGS

FIG. 1 is a cross-sectional views showing a method of manufacturing a dielectric memory device according to an embodiment of the present invention;

FIG. 2 is a cross-sectional view showing a method of manufacturing a dielectric memory device following FIG. 1 according to the embodiment;

FIG. 3 is a cross-sectional view showing a method of manufacturing a dielectric memory device following FIG. 2 according to the embodiment;

FIG. 4 is a cross-sectional view showing a method of manufacturing a dielectric memory device following FIG. 3 according to the embodiment;

FIG. 5 is a cross-sectional view of a ferroelectric capacitor FC including the second lower electrode 216 made of SRO;

FIG. 6 is a cross-sectional view of a ferroelectric capacitor that does not include the second lower electrode 216;

FIG. 7 is a graph showing polarization characteristics of the ferroelectric capacitor including the second lower electrode 216 according to the embodiment;

FIG. 8 is a graph showing polarization characteristics of the ferroelectric capacitor including the second lower electrode 216 according to the embodiment;

FIG. 9 is a graph showing polarization characteristics of the ferroelectric capacitor that does not include the second lower electrode 216;

FIG. 10 is a graph showing polarization characteristics of the ferroelectric capacitor that does not include the second lower electrode 216;

FIG. 11 is a graph showing the relationship between the thickness of the second lower electrode 216 and the switching charge amount and the relationship between the thickness of the second lower electrode 216 and the inversion electric field; and

FIG. 12 is a graph showing the relationship between the grain diameter of crystals of the ferroelectric film (PZT film) 217 and the thickness of the second lower electrode 216 made of SRO.

### DETAILED DESCRIPTION OF THE INVENTION

Embodiments of the present invention will be explained below in detail with reference to the accompanying drawings. Note that the invention is not limited thereto.

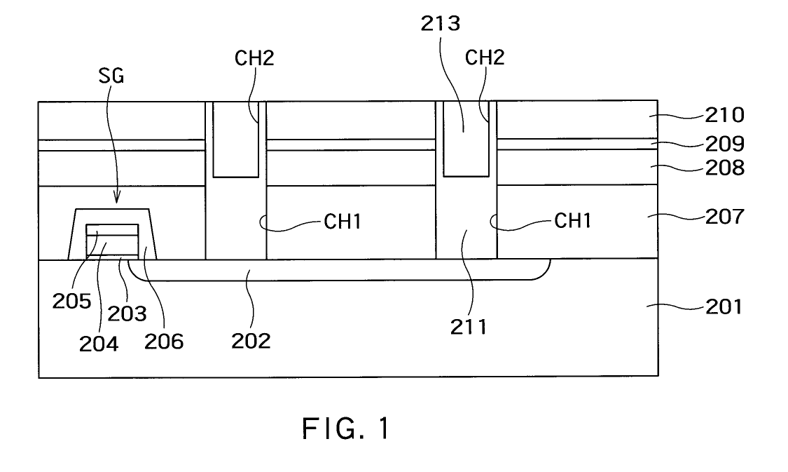

FIG. 1 to FIG. 4 are cross-sectional views showing a method of manufacturing a dielectric memory device according to an embodiment of the present invention. First, as shown in FIG. 1, a diffusion layer 202 that serves as an active region is formed on a silicon substrate 201. The diffusion layer 202 can be either a p-diffusion layer or n-diffusion layer. A selected gate SG, which is turned on when a memory cell corresponding to the selected gate is selected, is then formed. The selected gate SG includes a gate oxide film 203 provided on the silicon substrate 201, a gate electrode 204, a silicide layer 205, and a gate cap 206. The gate oxide film 203 can be formed by, for example, thermally oxidizing the silicon substrate 201. The gate electrode 204 can be formed by, for example, depositing polysilicon and patterning the polysilicon by lithography. The silicide layer 205 can be formed by depositing a metal film such as a titanium film on the gate electrode 204 and causing the metal film to react with the gate electrode 204. The gate cap 206 can be formed by, for example, depositing a silicon oxide film or a silicon nitride film and patterning the silicon oxide film or silicon nitride film by lithography.

As shown in FIG. 1, an insulating film 207 is formed to cover up the selected gate SG. The insulating film 207 can be formed by, for example, depositing a silicon oxide film and flattening the silicon oxide film by CMP (Chemical Mechanical Polishing) or the like. Multi-interlayer dielectric films 208, 209, and 210 are deposited on the insulating film 207. The multi-interlayer dielectric films 208, 209, and 210 are insulating films such as TEOS, silicon oxide films, or silicon nitride films.

Contact holes CH1 penetrating through the multi-interlayer dielectric films 208, 209, and 210 and the insulating film 207 and reaching the diffusion layer 202 are formed using RIE (Reactive Ion Etching) or the like. Polysilicon plugs 211 and tungsten plugs 213 are filled up in the contact holes CH1. The polysilicon plugs 211 and tungsten plugs 213 can be formed by a so-called damascene method. For example, polysilicon is deposited, the polysilicon is polished by the CMP or the like, and the resultant polysilicon is filled up in the contact holes CH1. The polysilicon plugs 211 are thereby formed. Using the lithography and the RIE, contact holes CH2 are further formed in the polysilicon plugs 211, respectively. A barrier layer 212 made of Ti.TiN or Ti is deposited on an inner wall of each contact hole CH2 and a heat treatment is then carried out on the barrier layer 212 in forming gas atmosphere. Tungsten is deposited by a CVD method and a tungsten film is polished by the CMP method. The tungsten plugs 213 are thereby formed in the contact holes CH2, respectively.

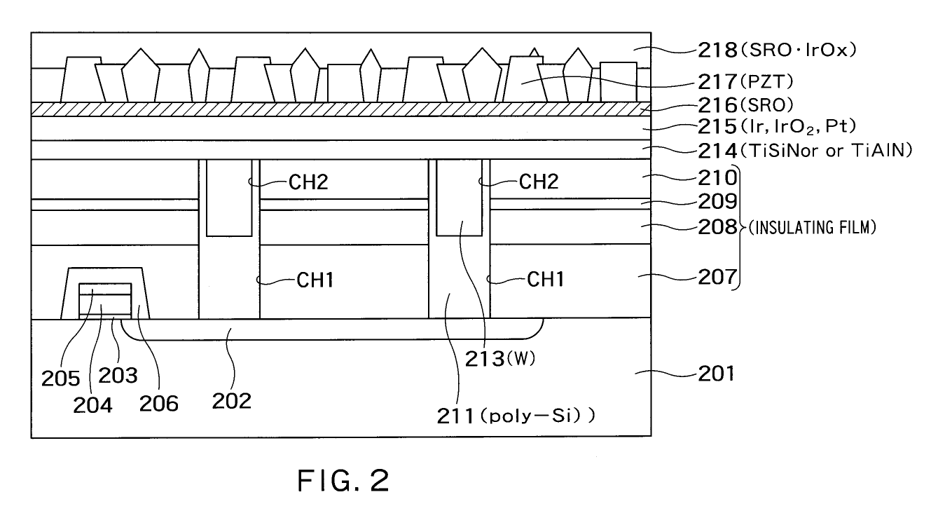

As shown in FIG. 2, a barrier layer 214 is formed to be connected to the tungsten plugs 213. The barrier layer 214 is constituted by, for example, a TiSiN film or a TiAlN film. A first lower electrode 215 is deposited on the barrier layer 214 by a sputtering method or the CVD method. The first lower electrode 215 is made of, for example, Ir, IrO₂, Pt, or a multilayer film thereof. A second lower electrode 216 is deposited on the first lower electrode 215 by the sputtering method or the CVD method. The second lower electrode 216 is made of SRO (Strontium Ruthenium Oxide). The second lower electrode 216 has a thickness in a range from about 5 to 50 nm. The effect of the thickness of the second lower electrode 216 will be described later.

A ferroelectric film such as a Pb(Zr, Ti) O₃ film (PZT film) is deposited as a capacitor dielectric film 217 on the second lower electrode 216 by an MOCVD (Metal-Oxide Chemical Vapor Deposition) method. If the ferroelectric film, i.e., capacitor dielectric film 217 is formed on the second lower electrode 216 having a thickness of about 5 to 50 nm and made of SRO, a grain diameter of crystals of the dielectric film is in a range from about 30 to 150 nm. The grain diameter of crystals of the ferroelectric film will be described later. Crystal grains of the PZT film, i.e., capacitor dielectric film 217 formed by the MOCVD method can be made smaller in size by in situ crystallization.

The inventers of the present invention discovered that the size of the crystal grains of the PZT film become very small, when the PZT film is formed on an SRO film by using in situ crystallization with MOCVD method. The in situ crystallization is a process in which PZT film is directly crystallized on the SRO film using MOCVD method in a high temperature atmosphere, for example over 600° C. According to the in situ crystallization, the PZT film is formed in a crystalline state.

Thereafter, an SRO film and an IrOx film are deposited on the capacitor dielectric film 217 in order by the sputtering method or the CVD method. As a result, an upper electrode 218 constituted by an SRO/IrOx multilayer film is formed.

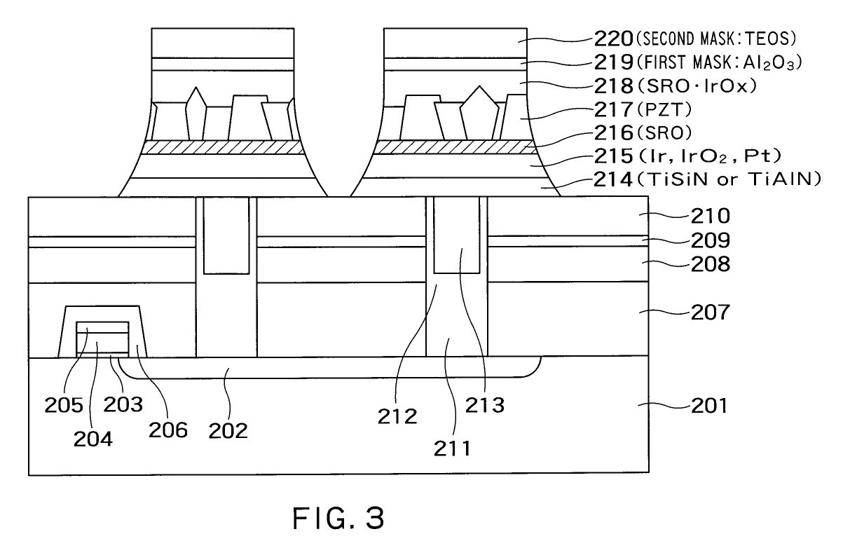

An Al₂O₃ film serving as a first mask material and a TEOS film serving as a second mask material are deposited on the upper electrode 218 by the sputtering method or the CVD method. As shown in FIG. 3, a second mask 220 is formed by processing the second mask material. The first mask material is processed using the second mask 220 as a mask, thereby forming a first mask 219.

Next, as shown in FIG. 3, the upper electrode 218, the capacitor dielectric film 217, the second lower electrode 216, the first lower electrode 215, and the barrier layer 214 are etched by the RIE using the first and second masks 219 and 220 as a mask.

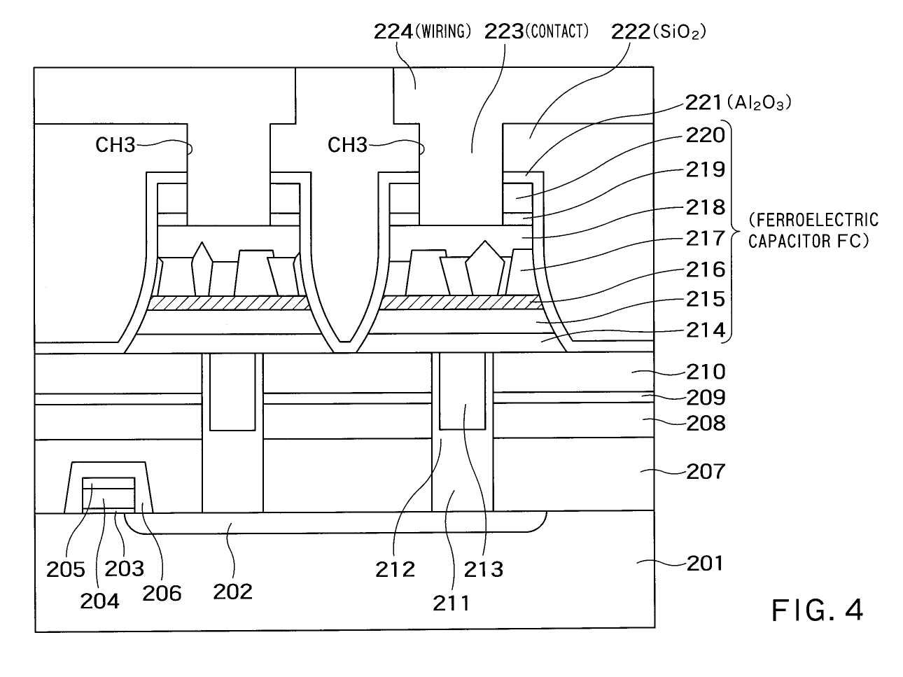

As shown in FIG. 4, an Al₂O₃ film 221 serving as a reduction atmosphere anti-diffusion film and an SiO₂ film 222 serving as an interlayer dielectric film are then deposited in order by the sputtering or the CVD. The Al₂O₃ film 221 and the SiO₂ film 222 are flattened by the CMP. The Al₂O₃ film 221, the SiO₂ film 222, the second mask 220, and the first mask 219 are etched by the lithography and the RIE, thereby forming contact holes CH3 reaching the upper electrode 218. Thereafter, wiring gutters are formed by the lithography and the RIE. A barrier film (not shown) is deposited in each of the contact holes CH3 and the wiring trenches by the sputtering or the CVD, and an Al film, a W film, or an Al—Cu alloy film is buried in the contact holes CH3. Namely, contacts 223 and wirings 224 are formed by a dual damascene method. Thereafter, to relax plasma damage produced in the ferroelectric layer, i.e., capacitor dielectric film 217, recovery annealing is performed for about one hour in an oxygen atmosphere at 450° C. to 650° C. As a consequence, a ferroelectric memory device is completed.

As shown in FIG. 3, the ferroelectric memory device includes the insulating films 207 to 217 provided on the silicon substrate 201, the polysilicon and tungsten plugs 211 and 213 serving as lower contacts formed on the insulating films 207 to 210, a ferroelectric capacitor FC, and wirings 224. The ferroelectric capacitor FC includes the first lower electrode 215 provided on and connected to the lower contacts 211 and 213, the second lower electrode 216 provided on the first lower electrode 215 and made of SRO, the ferroelectric film 217 made of crystals at the crystal grain diameter of 30 nm to 150 nm by being formed on the second lower electrode 216, and the upper electrode 218 provided on the ferroelectric film 217. Each of the wirings 224 is connected to the upper electrode 218 via one contact 223.

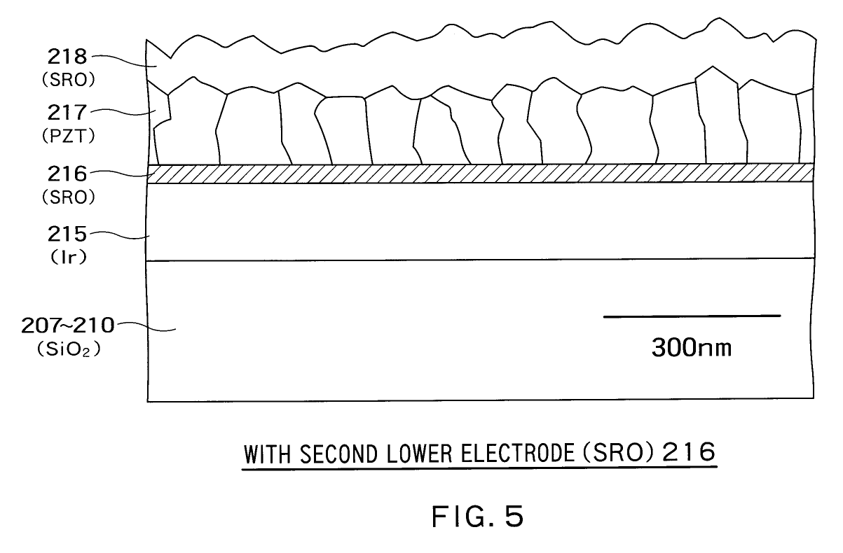

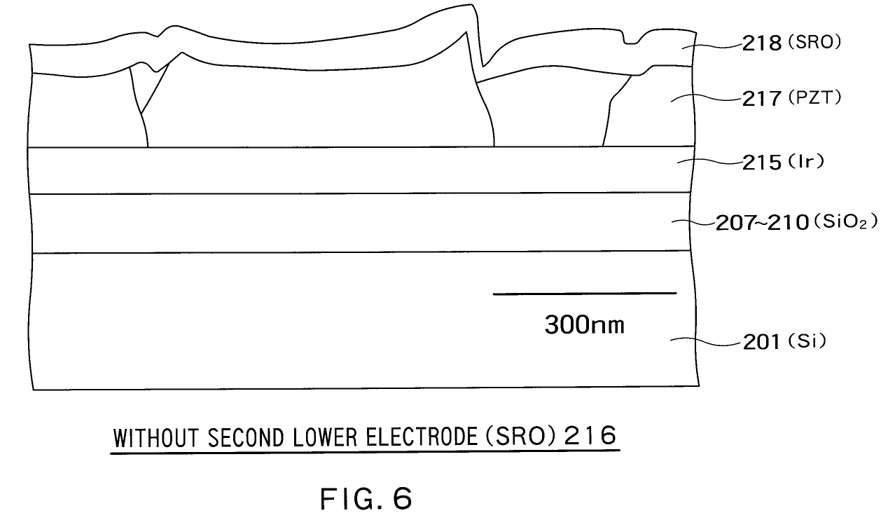

FIG. 5 is a cross-sectional view of a ferroelectric capacitor FC including the second lower electrode 216 made of SRO. FIG. 6 is a cross-sectional view of a ferroelectric capacitor FC that does not include the second lower electrode 216. These cross-sectional views schematically show photographs taken by a TEM (transmission electron microscope), respectively. In FIGS. 5 and 6, the barrier layer 214 is not shown. As evident from comparison between FIGS. 5 and 6, the grain diameter of crystals of the ferroelectric film 217 shown in FIG. 5 is smaller than that of crystals of the ferroelectric film 217 shown in FIG. 6. The grain diameter of crystals of the ferroelectric film 217 shown in FIG. 5 is about 30 to 150 nm. The grain diameter of crystals of the ferroelectric film 217 shown in FIG. 6 is about 200 to 600 nm or more.

The reason for such a difference in the grain diameter of crystals of the ferroelectric film 217 is the difference in a foundation material of the ferroelectric film 217. If the ferroelectric film 217 does not include the second lower electrode 216 made of SRO as seen in the conventional technique, the foundation material is the first lower electrode 215. The first lower electrode 215 is made of an Ir, IrO₂, Pt, or a multilayer film thereof. In this case, the grain diameter of crystals of the ferroelectric film 217 is large as shown in FIG. 6.

On the other hand, the ferroelectric capacitor CF according to the embodiment has the ferroelectric film 217 formed on the second lower electrode 216 made of SRO. Further, the PZT film, i.e., ferroelectric film 217 is formed by the in situ crystallization using the MOCVD. Due to this, as shown in FIG. 5, the grain diameter of crystals of the ferroelectric film 217 can be made relatively small.

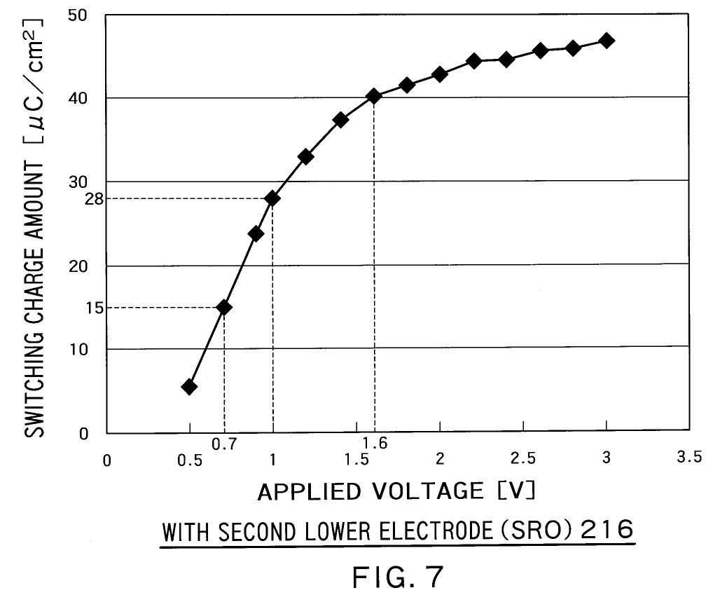

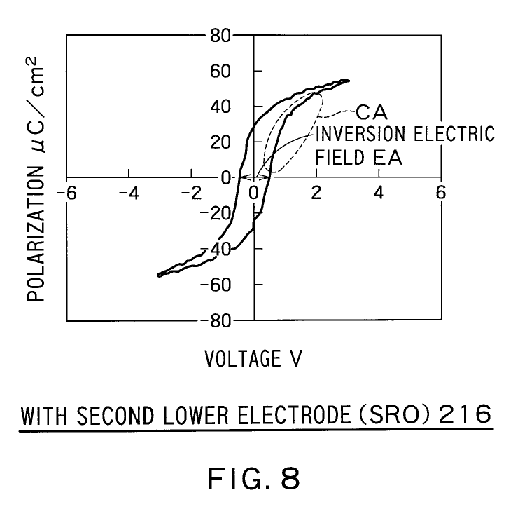

FIG. 7 and FIG. 8 are graphs showing polarization characteristics of the ferroelectric capacitor FC including the second lower electrode 216 according to the embodiment. In FIGS. 7 and 8, the horizontal axis indicates the applied voltage between the upper electrode 218 and the lower electrodes 215 and 216. The vertical axis indicates a polarization amount (hereinafter, also “switching charge amount”) of the ferroelectric capacitor FC. FIG. 8 is a graph showing overall hysteresis of the polarization characteristics of the ferroelectric capacitor FC. FIG. 7 shows a part indicated by a broken-line circle CA of the hysteresis shown in FIG. 8 in detail.

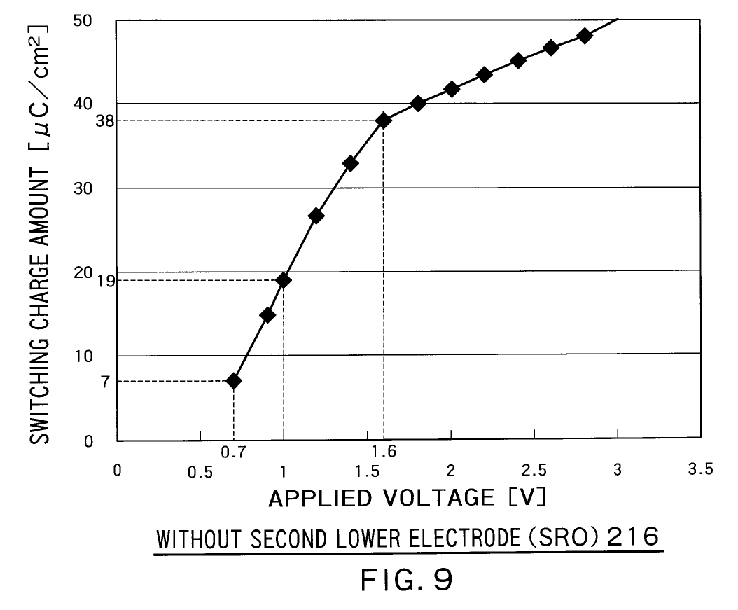

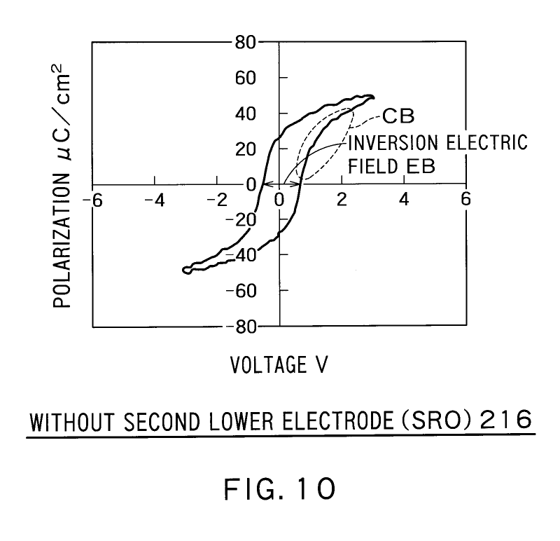

FIG. 9 and FIG. 10 are graphs showing polarization characteristics of the ferroelectric capacitor FC that does not include the second lower electrode 216. FIG. 10 is a graph showing overall hysteresis of the polarization characteristics of the ferroelectric capacitor FC. FIG. 9 shows a part indicated by a broken-line circle CA of the hysteresis shown in FIG. 10 in detail.

FIG. 7 and FIG. 9 are compared. In case of the ferroelectric capacitor FC according to the embodiment shown in FIG. 7, even if the applied voltage between the upper electrode 218 and the lower electrodes 215 and 216 is low, a large amount of switching charge is accumulated in the ferroelectric capacitor FC. For example, if the applied voltage is 0.7 V, the switching charge amount is about 7 μC/cm² in the graph of FIG. 9 and about 15 μC/cm² in the graph of FIG. 7. If the applied voltage is 1 V, the switching charge amount is about 19 μC/cm² in the graph of FIG. 9 and about 28 μC/cm² in the graph of FIG. 7. In this way, even if the applied voltage is low, the ferroelectric capacitor FC according to the embodiment can accumulate a relatively large amount of charge. This can produce the effect of reducing the inversion electric field. The inversion electric field reduction effect is obvious from the comparison between FIGS. 8 and 10. If the inversion electric field EA shown in FIG. 8 is compared with the inversion electric field EB shown in FIG. 10, the inversion electric field EA is obviously lower than the inversion electric field EB.

By forming the ferroelectric film 217 on the second lower electrode 216 made of SRO as seen in the embodiment, the grain diameter of crystals of the ferroelectric film 217 can be set as small as 30 nm to 150 nm. Further, by setting the grain diameter of crystals of the ferroelectric film 217 as small as 30 nm to 150 nm, the inversion electric field can be set low. If the inversion electric field is low, the polarization of the ferroelectric capacitor FC can be inverted at low applied voltage. As a result, malfunctioning of the ferroelectric capacitor can be improved and the ferroelectric memory device having high reliability can be realized.

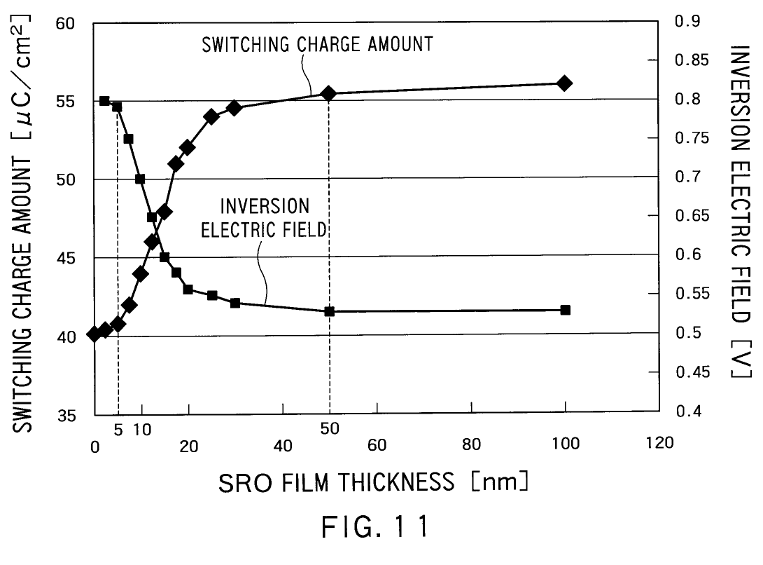

FIG. 11 is a graph showing the relationship between the thickness of the second lower electrode 216 and the switching charge amount and the relationship between the thickness of the second lower electrode 216 and the inversion electric field. If the thickness of the second lower electrode 216 is as small as less than 5 nm, the inversion electric field remains high and the switching charge amount remains small. Namely, if the thickness of the second lower electrode 216 is as small as less than 5 nm, the above-stated effect of the embodiment is small.

If the thickness of the second lower electrode 216 is equal to or larger than 5 nm, the inversion electric field starts falling and the switching charge amount starts rising. If the thickness of the second lower electrode 216 is as large as 50 nm or more, the inversion electric field and the switching charge amount saturate. If the thickness of the second lower electrode 216 is large, the etching by the RIE described with reference to FIG. 3 is difficult to carry out. Namely, the ferroelectric capacitor FC is difficult to work (it is difficult to separate the ferroelectric capacitor FC from the other elements), with the result that a fence of the ferroelectric capacitor is easy to adhere to an end of the upper electrode 218. This fence deteriorates coatability of the Al₂O₃ film 221 serving as the reduction atmosphere anti-diffusion film. As a result, the Al₂O₃ film 221 cannot prevent hydrogen generated in a back-end process from diffusing into the ferroelectric capacitor FC. This may possibly cause device defect. It is, therefore, preferable that the thickness of the second lower electrode is 5 nm to 50 nm.

If the thickness of the second lower electrode 216 is equal to or larger than 5 nm, the inversion electric field greatly lowers and the switching charge amount rises. It is considered that the reason is rising of the density of the inversion center of the polarization of the ferroelectric capacitor FC.

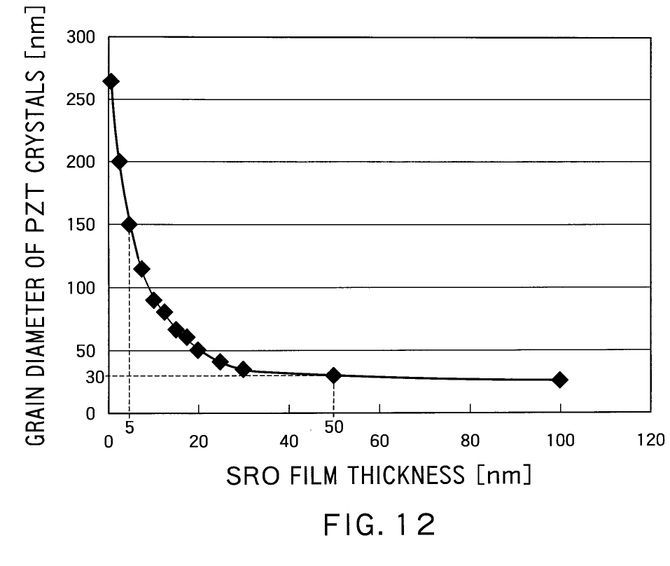

FIG. 12 is a graph showing the relationship between the grain diameter of crystals of the ferroelectric film (PZT film) 217 and the thickness of the second lower electrode 216 made of SRO. If the thickness of the second lower electrode 216 is about 5 to 50 nm, the grain diameter of the ferroelectric film 217 is about 30 to 150 nm. That is, by setting the grain diameter of the ferroelectric film 217 to about 30 to 150 nm, the switching charge amount Qsw and the inversion electric field can be set in the preferable ranges shown in FIG. 11, respectively.

1. A semiconductor device comprising:
an insulating film provided on a semiconductor substrate;
a lower contact formed in the insulating film;
a ferroelectric capacitor including a first lower electrode provided on the lower contact and connected to the lower contact, a second lower electrode provided on the first lower electrode and made of SRO (Strontium Ruthenium Oxide), a ferroelectric film including crystals, and an upper electrode provided on the ferroelectric film, grain diameters of the crystals being set to 30 nm to 150 nm by forming the ferroelectric film on the second lower electrode; and
a wiring connected to the upper electrode.

2. The semiconductor device according to claim 1, wherein a thickness of the second lower electrode is equal to or larger than 5 nm.

3. The semiconductor device according to claim 1, wherein a thickness of the second lower electrode is equal to or larger than 5 to 50 nm.

4. The semiconductor device according to claim 1, wherein the ferroelectric film is a PZT film formed by an MOCVD (Metal-Oxide Chemical Vapor Deposition) method.

5. A semiconductor device comprising:
an insulating film provided on a semiconductor substrate;
a lower contact formed in the insulating film;
a ferroelectric capacitor including a first lower electrode provided on the lower contact and connected to the lower contact, a second lower electrode provided on the first lower electrode, a ferroelectric film formed on the second lower electrode, and an upper electrode provided on the ferroelectric film, the second lower electrode being made of SRO and having a thickness equal to or larger than 5 nm; and
a wiring connected to the upper electrode.

6. The semiconductor device according to claim 5, wherein the ferroelectric film is a PZT film formed by an MOCVD (Metal-Oxide Chemical Vapor Deposition) method.

7. A method of manufacturing a semiconductor device, comprising:
forming an insulating film on a semiconductor substrate;
forming a lower contact in the insulating film;
forming a first lower electrode on the lower contact to be connected to the lower contact;
forming a second lower electrode made of SRO on the first lower electrode;
forming a ferroelectric film on the second lower electrode to set grain diameters of crystals of the ferroelectric film to 30 nm to 150;
forming an upper electrode on the ferroelectric film; and
forming a wiring to be connected to the upper electrode.

8. The semiconductor device according to claim 7, wherein the ferroelectric film is a PZT film formed by an MOCVD (Metal-Oxide Chemical Vapor Deposition) method.
